(19) United States
(12) Patent Application Publication
(10) Pub. No.: US 2026/0354039 A1
(43) Pub. Date: Nov. 5, 2026

(54) IN-SITU JOSEPHSON JUNCTION FABRICATION BY OBLIQUE DEPOSITION

(71) Applicant: TOKYO ELECTRON LIMITED, Tokyo (JP)

(72) Inventors: Hunter FROST, Albany, NY (US); Gerrit LEUSINK, Albany, NY (US)

(73) Assignee: TOKYO ELECTRON LIMITED, Tokyo (JP)

(21) Appl. No.: 19/196,646

(22) Filed: May 1, 2025

(51) Int. Cl. H10N 60/12; H10N 60/01; H10N 69/00

(52) U.S. Cl. CPC H10N 60/12; H10N 60/0912; H10N 69/00

(57) ABSTRACT

A semiconductor device includes a substrate, a fin structure formed on the substrate, a first superconducting electrode, a tunnel barrier and a second superconducting electrode. In a vertical direction that is substantially perpendicular to a working surface of the substrate, a first portion of the second superconducting electrode is formed on a first portion of the tunnel barrier that is formed on a first portion of the first superconducting electrode which is formed on a top surface of the fin structure. In a horizontal direction that is substantially parallel to the working surface of the substrate, a second portion of the first superconducting electrode is formed on a first side surface of the fin structure, and a second portion of the second superconducting electrode is formed on a second portion of the tunnel barrier that is formed on a second side surface of the fin structure.

### INCORPORATION BY REFERENCE

Aspects of the present disclosure are related to Applicant's co-pending U.S. patent application Ser. No. 18/830,058 and issued U.S. Pat. Nos. 11,495,446 B2 and 11,220,741 B2, all of which are incorporated herein by reference in their entirety.

### FIELD OF THE INVENTION

This disclosure relates to microelectronic devices including semiconductor devices, transistors and integrated circuits, and methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Complementary metal-oxide-semiconductor (CMOS) is a type of metal-oxide-semiconductor field-effect transistor (MOSFET) fabrication process that uses complementary and symmetrical pairs of p-type and n-type MOSFETs for logic functions. CMOS technology is traditionally used for constructing integrated circuit (IC) chips, including microprocessors, microcontrollers, memory chips (including CMOS BIOS), and other digital logic circuits. CMOS technology is also used for analog circuits such as image sensors (CMOS sensors), data converters, RF circuits (RF CMOS), and highly integrated transceivers for many types of communication. Beyond CMOS refers to the possible future digital logic technologies beyond the scaling limits of CMOS technology, which limit device density and speeds due to heating effects.

### SUMMARY

The present disclosure relates to a semiconductor device and a method of forming the same.

According to a first aspect of the disclosure, a semiconductor device is provided. The semiconductor device includes a substrate, a fin structure formed on the substrate, a first superconducting electrode, a tunnel barrier and a second superconducting electrode. In a vertical direction that is substantially perpendicular to a working surface of the substrate, a first portion of the second superconducting electrode is formed on a first portion of the tunnel barrier that is formed on a first portion of the first superconducting electrode which is formed on a top surface of the fin structure. In a horizontal direction that is substantially parallel to the working surface of the substrate, a second portion of the first superconducting electrode is formed on a first side surface of the fin structure, and a second portion of the second superconducting electrode is formed on a second portion of the tunnel barrier that is formed on a second side surface of the fin structure.

In some embodiments, the first side surface of the fin structure and the second side surface of the fin structure are on opposite sides of the fin structure.

In some embodiments, the second portion of the tunnel barrier is in direct contact with an edge of the first portion of the first superconducting electrode.

In some embodiments, the tunnel barrier is L-shaped.

In some embodiments, the first superconducting electrode and the second superconducting electrode each independently include one selected from the group consisting of an elemental superconducting metal, a superconducting alloy and a superconducting nitride.

In some embodiments, the elemental superconducting metal includes niobium (Nb), tantalum (Ta), aluminum (Al) or a combination thereof. The superconducting alloy includes NbTi, WSi or a combination thereof. The superconducting nitride includes NbN, NbTiN or a combination thereof.

In some embodiments, the tunnel barrier includes one selected from the group consisting of a non-superconducting metal nitride and a non-superconducting metal oxide.

In some embodiments, the non-superconducting metal nitride includes tantalum nitride, aluminum nitride or a combination thereof. The non-superconducting metal oxide includes tantalum oxide, aluminum oxide or a combination thereof.

In some embodiments, the semiconductor device further includes a short-circuited junction structure. The short-circuited junction structure includes a third portion of the first superconducting electrode, a tunnel barrier layer formed over the third portion of the first superconducting electrode, and a top electrode layer formed over the tunnel barrier layer and around an edge of the tunnel barrier layer to be in direct contact with the third portion of the first superconducting electrode.

In some embodiments, the semiconductor device further includes a short-circuited junction structure. The short-circuited junction structure includes a bottom electrode layer, a tunnel barrier layer formed over the bottom electrode layer, and a third portion of the second superconducting electrode formed over the tunnel barrier layer and around an edge of the tunnel barrier layer to be in direct contact with the bottom electrode layer.

In some embodiments, the second superconducting electrode has a recess between the second portion of the second superconducting electrode and the third portion of the second superconducting electrode.

In some embodiments, the semiconductor device further includes a reaction barrier layer formed between the fin structure and the first superconducting electrode and between the fin structure and the tunnel barrier. The reaction barrier layer is respectively in direct contact with the fin structure, the first superconducting electrode and the tunnel barrier.

According to a second aspect of the disclosure, a method of manufacturing a semiconductor device is provided. The method includes forming a first superconducting electrode over a fin structure on a substrate, forming a tunnel barrier over the first superconducting electrode, and forming a second superconducting electrode over the tunnel barrier. In a vertical direction that is substantially perpendicular to a working surface of the substrate, a first portion of the second superconducting electrode is formed on a first portion of the tunnel barrier that is formed on a first portion of the first superconducting electrode which is formed on a top surface of the fin structure. In a horizontal direction that is substantially parallel to the working surface of the substrate, a second portion of the first superconducting electrode is formed on a first side surface of the fin structure, and a second portion of the second superconducting electrode is formed on a second portion of the tunnel barrier that is formed on a second side surface of the fin structure.

In some embodiments, a first oblique deposition process directed towards the first side surface of the fin structure is executed to form the first superconducting electrode.

In some embodiments, a second oblique deposition process directed towards the second side surface of the fin structure is executed to form the tunnel barrier.

In some embodiments, a third oblique deposition process directed towards the second side surface of the fin structure is executed to form the second superconducting electrode.

In some embodiments, the first oblique deposition process, the second oblique deposition process and the third oblique deposition process are executed in a common deposition chamber.

In some embodiments, executing the second oblique deposition process includes forming the tunnel barrier in situ on the first superconducting electrode without an oxide-removing process.

In some embodiments, the substrate is rotated by about 180 degrees between executing the first oblique deposition process and executing the second oblique deposition process.

In some embodiments, a reaction barrier layer is formed over the fin structure before executing the first oblique deposition process, the second oblique deposition process and the third oblique deposition process.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. Changes and modifications may be made within the scope herein without departing from the spirit and scope thereof. It is noted that, in accordance with the standard practice in the industry, various features are not drawn to scale. In fact, the dimensions of the various features may be increased or reduced for clarity of discussion.

FIGS. 1A and 1B respectively show a vertical cross-sectional view and a top view of a semiconductor device in accordance with some embodiments of the present disclosure.

FIG. 1C shows a vertical cross-sectional view of a semiconductor device in accordance with some embodiments of the present disclosure.

FIG. 2 shows a flow chart of a process for manufacturing a semiconductor device, in accordance with some embodiments of the present disclosure.

FIGS. 3A, 3B, 3C, 3D, 3E, 3F and 3G show vertical cross-sectional views of a semiconductor device at various intermediate steps of manufacturing, in accordance with some embodiments of the present disclosure.

FIG. 4 shows a vertical cross-sectional view of a deposition chamber in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “between . . . and . . . ”, “to”, “from . . . to . . . ”, “-” and similar terms includes numerical values at both ends, unless specified otherwise.

As noted in the Background, beyond CMOS refers to potential future digital logic technologies that expand beyond the present CMOS scaling limits. However, beyond CMOS technologies, which include quantum computing with superconducting qubits, face many fabrication/process control challenges. Particularly, creating pristine Josephson junctions with clean interfaces is a critical challenge.

A Josephson junction can be made by sandwiching a thin layer of a non-superconducting material between two layers of superconducting material, also known as the top and bottom superconducting electrodes. This thin layer of the non-superconducting material can be in the form of a tunnel barrier. Josephson junctions can be fabricated with a two-mask-level process, requiring a pre-clean/pre-sputter process before tunnel barrier deposition to clean the metal electrode, for example as disclosed in Applicant's co-pending U.S. patent application Ser. No. 18/830,058 which is incorporated herein by reference in its entirety.

Techniques herein provide a method for in-situ Josephson junction fabrication with oblique deposition such as physical vapor deposition (PVD). Josephson junctions can be created entirely in situ, with no air breaks and no wafer transfer between different deposition chambers. Accordingly, a Josephson junction can be obtained with a single lithography mask. Such an integration scheme simplifies Josephson junction processing while simultaneously creating “clean” junctions through in-situ deposition and allowing a variety of material systems, including metal nitride and metal oxide barriers. The use of an oblique deposition system (e.g. PVD) yields improved uniformity for tunnel barrier thickness and superconducting electrode thicknesses. The in-situ feature of the method offers the simplicity and ability to fabricate scalable Josephson junctions without breaking vacuum for tunnel barrier and superconducting electrode deposition and without transferring the wafer from one deposition chamber to another.

According to aspects of the present disclosure, a single in-situ deposition of Josephson junction stack can offer numerous advantages such as no pre-cleans of metal oxides, no vacuum breaks, no unnecessary protective films, no unnecessary wafer transfer between chambers, etc. Directional PVD allows for a single Josephson junction lithography mask.

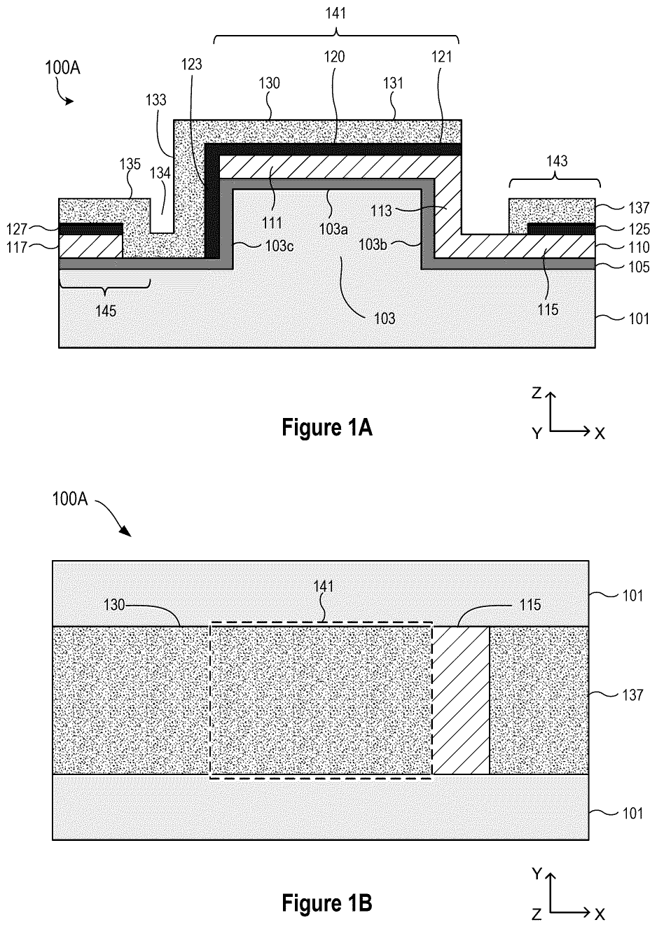

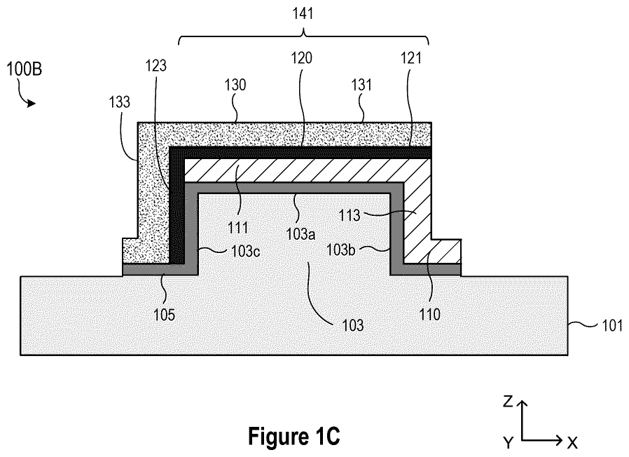

FIGS. 1A and 1B respectively show a vertical cross-sectional view and a top view of a semiconductor device (hereinafter referred to as a device 100A) in accordance with some embodiments of the present disclosure. As illustrated, the device 100A includes a substrate 101 and a fin structure 103 formed on the substrate 101. A reaction barrier layer 105 can be formed over the substrate 101 and the fin structure 103. The device 100A also includes a first superconducting electrode 110 (also referred to as a bottom superconducting electrode), a tunnel barrier 120 and a second superconducting electrode 130 (also referred to as a top superconducting electrode).

In the Z direction, a first portion 131 of the second superconducting electrode 130 is formed on a first portion 121 of the tunnel barrier 120 that is formed on a first portion 111 of the first superconducting electrode 110 which is formed on a top surface 103a of the fin structure 103. Along the X direction, a second portion 113 of the first superconducting electrode 110 is formed on a first side surface 103b of the fin structure 103, and a second portion 133 of the second superconducting electrode 130 is formed on a second portion 123 of the tunnel barrier 120 that is formed on a second side surface 103c of the fin structure 103. As a result, the device 100A can include a Josephson junction structure 141 that includes the first portion 111 of the first superconducting electrode 110, the first portion 121 of the tunnel barrier 120 and the first portion 131 of the second superconducting electrode 130.

In some embodiments, the device 100A can include a first short-circuited junction structure 143 that includes a third portion 115 of the first superconducting electrode 110, a tunnel barrier layer 125 formed over the third portion 115 of the first superconducting electrode 110 and a top electrode layer 137 formed over the tunnel barrier layer 125. Note that the top electrode layer 137 is also formed around an edge of the tunnel barrier layer 125 and is thus in direct contact with the third portion 115 of the first superconducting electrode 110.

In some embodiments, the device 100A can include a second short-circuited junction structure 145 that includes a bottom electrode layer 117, a tunnel barrier layer 127 formed over the bottom electrode layer 117 and a third portion 135 of the second superconducting electrode 130 formed over the tunnel barrier layer 127. Note that the third portion 135 of the second superconducting electrode 130 is also formed around an edge of the tunnel barrier layer 127 and is thus in direct contact with the bottom electrode layer 117. Additionally, the second superconducting electrode 130 can have a recess 134 between the second portion 133 and the third portion 135.

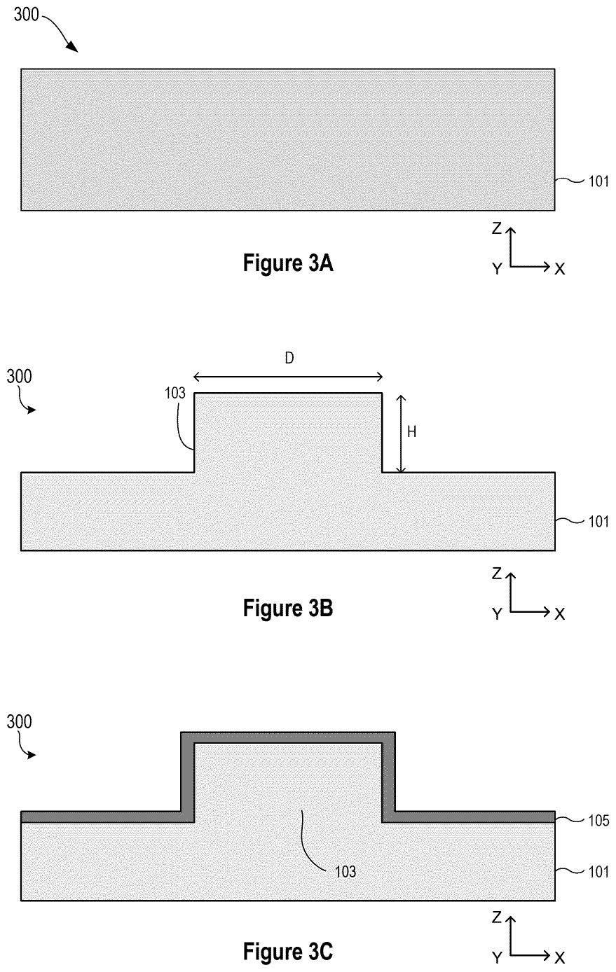

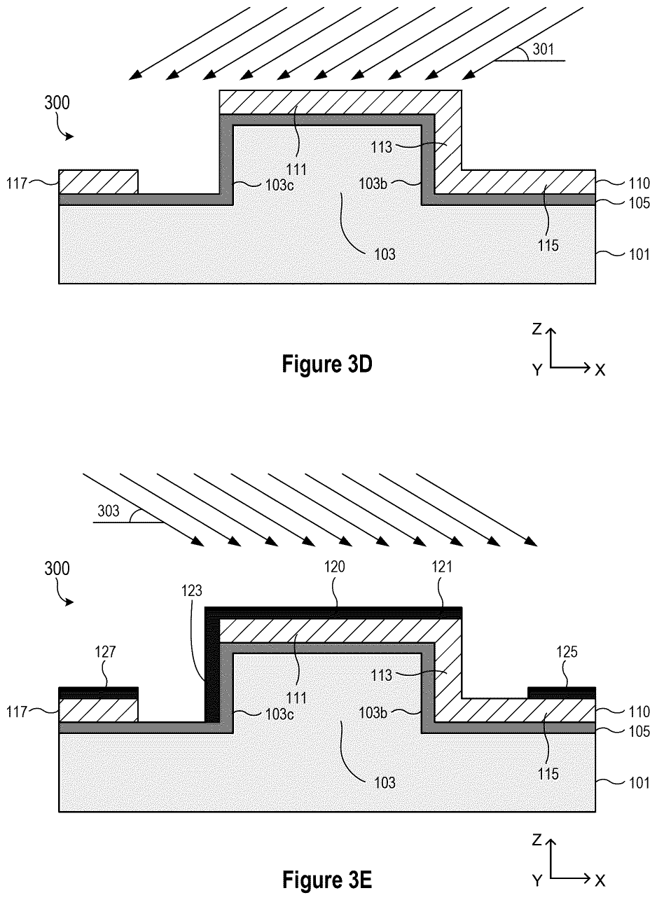

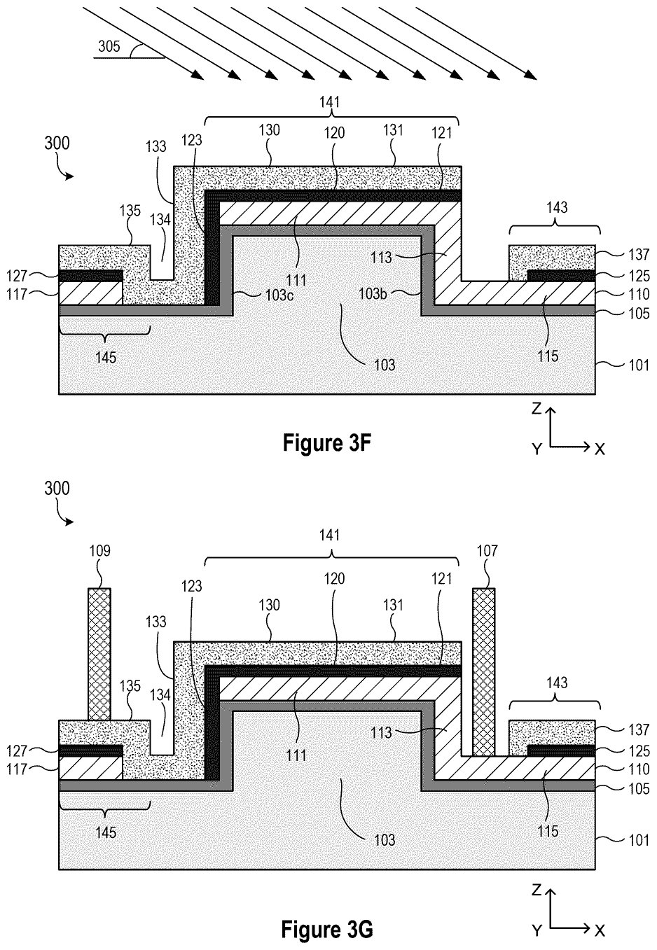

As will be explained in detail later (see e.g. FIGS. 3D, 3E and 3F), the first superconducting electrode 110 and the bottom electrode layer 117 can be formed in the same deposition process and thus include the same material(s). The tunnel barrier 120, the tunnel barrier layer 125 and the tunnel barrier layer 127 can be formed in the same deposition process and thus include the same material(s). The second superconducting electrode 130 and the top electrode layer 137 can be formed in the same deposition process and thus include the same material(s).

In some preferred embodiments, the first superconducting electrode 110 and the second superconducting electrode 130 each independently include niobium, tantalum, aluminum, NbN or NbTiN. The first superconducting electrode 110 and the second superconducting electrode 130 may or may not include the same material(s). The tunnel barrier 120 includes tantalum nitride, aluminum nitride, tantalum oxide or aluminum oxide. The substrate 101 includes silicon or sapphire.

More generally, the first superconducting electrode 110 and the second superconducting electrode 130 can each independently include at least one selected from the group consisting of an elemental superconducting metal, a superconducting alloy and a superconducting nitride. Examples of the first superconducting electrode 110 and the second superconducting electrode 130 described below can be used individually or in any combination.

Examples of the elemental superconducting metal can include, but are not limited to, lead (Pb), lanthanum (La), tantalum (Ta), mercury (Hg), tin (Sn), indium (In), palladium (Pd), chromium (Cr), thallium (Tl), rhenium (Re), protactinium (Pa), thorium (Th), aluminum (Al), gallium (Ga), molybdenum (Mo), zinc (Zn), osmium (Os), zirconium (Zr), americium (Am), cadmium (Cd), ruthenium (Ru), titanium (Ti), uranium (U), hafnium (Hf), iridium (Ir), beryllium (Be), tungsten (W), platinum (Pt), lithium (Li), rhodium (Rh), yttrium (Y) and bismuth (Bi). Preferably, examples of the elemental superconducting metal can include Nb, Ta, Al, La, In, Cr, Zr, Ru and Ti. Preferably, examples of the elemental superconducting metal can include Nb, Ta and Al.

Examples of the superconducting alloy can include, but are not limited to, NbTi, WSi, NbZr, Nb₃Al, Nb₃Ge, Nb₃Sn and NbTi. Preferably, examples of the superconducting alloy can include NbTi, WSi, NbZr and NbTi. Preferably, examples of the superconducting alloy can include NbTi and WSi.

Examples of the superconducting nitride can include, but are not limited to, NbN, NbTiN, InN, TiN, ZrN, HfN, MoN and WN. Preferably, examples of the superconducting nitride can include NbN, NbTiN, InN, TiN and ZrN. Preferably, examples of the superconducting nitride can include NbN and NbTiN.

The tunnel barrier 120 can include at least one selected from the group consisting of a non-superconducting metal nitride, a non-superconducting metal oxide and a non-superconducting metal carbide. Examples of the tunnel barrier 120 described below can be used individually or in any combination.

Examples of the non-superconducting metal nitride can include, but are not limited to, tantalum nitride, aluminum nitride, copper nitride and gallium nitride. Preferably, examples of the non-superconducting metal nitride can include tantalum nitride and aluminum nitride.

Examples of the non-superconducting metal oxide can include, but are not limited to, tantalum oxide, aluminum oxide, zinc oxide and cobalt oxide. Preferably, examples of the non-superconducting metal oxide can include tantalum oxide and aluminum oxide.

Examples of the non-superconducting metal carbide can include, but are not limited to, tantalum carbide and aluminum carbide.

The reaction barrier layer 105 can include a dielectric material that does not contain oxygen and/or is not prone to surface oxidation. Particularly, the dielectric material can include a nitride material. Examples of the dielectric material include, but are not limited to, tantalum nitride, aluminum nitride and silicon nitride. Such examples can be used individually or in any combination. Preferably, the reaction barrier layer 105 includes tantalum nitride.

Regarding the substrate 101, “substrate” or “wafer” as used herein generically refers to an object being processed in accordance with the invention. The substrate 101 may include any material portion or structure of a device, particularly a semiconductor or other electronics device, and may, for example, be a base substrate structure, such as a semiconductor wafer, reticle, or a layer on or overlying a base substrate structure such as a thin film. Thus, the substrate 101 is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate 101 can be any suitable substrate, such as a silicon (Si) substrate, a germanium (Ge) substrate, a silicon-germanium (SiGe) substrate, a silicon-on-insulator (SOI) substrate and a sapphire substrate. The substrate 101 may include a semiconductor material such as a Group IV semiconductor, a Group III-V compound semiconductor, or a Group II-VI oxide semiconductor. The Group IV semiconductor may include Si, Ge, or SiGe. The substrate 101 may be a bulk wafer or an epitaxial layer. Preferably, the substrate 101 includes silicon or sapphire. Preferably, the substrate 101 includes silicon.

In the example of FIG. 1A, the fin structure 103 and the substrate 101 are integrally or seamlessly formed. Preferably, the fin structure 103 and the substrate 101 are made of silicon. In other examples, the fin structure 103 and the substrate 101 can include different materials; that is, the fin structure 103 is made of a different material that is formed over the substrate 101. Examples of the fin structure 103 are not particularly limited and may include any dielectric material including, but not limited to, silicon, silicon oxide, silicon nitride, etc. In addition, the shape of the fin structure 103 is used herein merely for illustrative purposes and protruding patterns of other shapes can be used as well.

Some examples described in the present disclosure have subscripts to indicate the number or ratio of atoms. For instance, Nb₃Al indicates the number of Nb to the number of Al has a ratio of 3. Some examples described in the present disclosure have no subscripts e.g. HfN, WN, TaN and SiGe. It should be understood that such notations do not necessarily mean that the ratio of corresponding atom numbers is 1:1. For instance, HfN can include Hf₃N₄, WN can include W₂N₃ and W₃N₄, TaN can include Ta₃N₅, and SiGe can include SiₓGe₁₋ₓ (0<x<1), as a skilled artisan would understand. In other words, when there are no subscripts, the ratio of corresponding atom numbers may be 1:1 or may not be 1:1, in which case the subscripts are omitted for simplicity purposes.

FIG. 1C shows a vertical cross-sectional view of a semiconductor device (hereinafter referred to as a device 100B) in accordance with some embodiments of the present disclosure. The embodiment of the device 100B is similar to the embodiment of the device 100A. Note that similar or identical components are labeled with similar or identical numerals in the present disclosure unless specified otherwise. Descriptions have been provided above and will be omitted for simplicity purposes. As shown, the device 100B does not include the first short-circuited junction structure 143 or the second short-circuited junction structure 145.

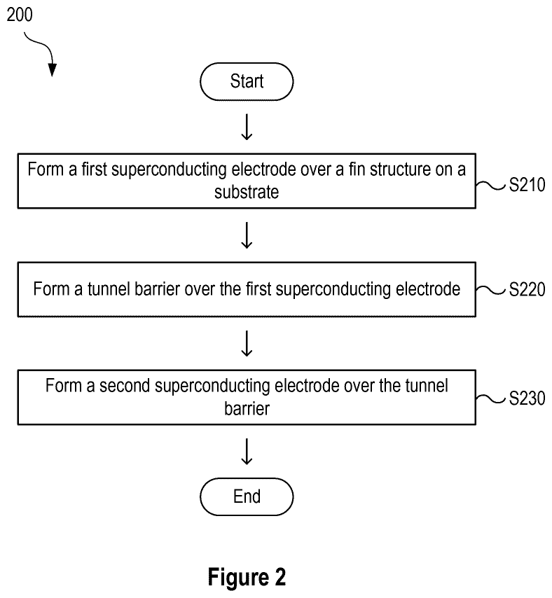

FIG. 2 shows a flow chart of a process 200 for manufacturing a semiconductor device (e.g. the device 100A, the device 100B and the like), in accordance with some embodiments of the present disclosure. At step S210, a first superconducting electrode is formed over a fin structure on a substrate, for example by a first oblique deposition process directed towards a first side surface of the fin structure. At Step S220, a tunnel barrier is formed over the first superconducting electrode, for example by a second oblique deposition process directed towards a second side surface of the fin structure. At step S230, a second superconducting electrode is formed over the tunnel barrier, for example by a third oblique deposition process directed towards the second side surface of the fin structure. In a vertical direction that is substantially perpendicular to a working surface of the substrate, a first portion of the second superconducting electrode is formed on a first portion of the tunnel barrier that is formed on a first portion of the first superconducting electrode which is formed on a top surface of the fin structure. In a horizontal direction that is substantially parallel to the working surface of the substrate, a second portion of the first superconducting electrode is formed on a first side surface of the fin structure, and a second portion of the second superconducting electrode is formed on a second portion of the tunnel barrier that is formed on a second side surface of the fin structure. The first side surface of the fin structure and the second side surface of the fin structure are on opposite sides of the fin structure.

FIGS. 3A, 3B, 3C, 3D, 3E, 3F and 3G show vertical cross-sectional views of a semiconductor device (hereinafter referred to as a device 300) at various intermediate steps of manufacturing, in accordance with some embodiments of the present disclosure. In FIG. 3A, the device 300 includes the substrate 101.

In FIG. 3B, the substrate 101 is patterned using a photomask (not shown) to form the fin structure 103. The fin structure 103 can have a width D of 30-800 nm e.g. 30 nm, 50 nm, 100 nm, 200 nm, 300 nm, 400 nm, 500 nm, 800 nm or any values therebetween. The fin structure 103 can have a height H of 30-800 nm e.g. 30 nm, 50 nm, 100 nm, 200 nm, 300 nm, 400 nm, 500 nm, 800 nm or any values therebetween. Preferably, D is from 100 nm to 500 nm, and H is from 50 nm to 300 nm. It should be noted that dimensions herein are discussed merely for illustrative purposes and are not limiting.

In the example of FIG. 3B, the fin structure 103 is part of a bulk semiconductor material of the substrate 101. In some embodiments, one or more dielectric materials such as silicon oxide and silicon nitride can be formed over the substrate 101 and patterned to form the fin structure 103.

In FIG. 3C, the reaction barrier layer 105 is formed over the substrate 101 and the fin structure 103, for example conformally by an atomic layer deposition process. The reaction barrier layer 105 can include tantalum nitride and have high resistivity isolation. A thickness of the reaction barrier layer 105 is not particularly limited and can for example be 1-10 nm e.g. 1 nm, 2 nm, 3 nm , 4 nm, 5 nm, 6 nm, 7 nm, 8 nm, 9 nm, 10 nm or any values therebetween.

In FIG. 3D, a first oblique physical vapor deposition (PVD) process directed towards the first side surface 103b of the fin structure 103 is executed to form the first superconducting electrode 110 and the bottom electrode layer 117. No deposition is accomplished on the second side surface 103c of the fin structure 103. Arrows herein represent vapor directions of PVD. A first angle 301 represents an angle between the vapor directions and the X direction. The first angle 301 is larger than 0° and smaller than 90°. Preferably, the first angle 301 is between 5° and 85° e.g. 5°, 10°, 20°, 30°, 40°, 45°, 50°, 60°, 70°, 80°, 85° or any values therebetween. Preferably, the first angle 301 is between 30° and 60°. Preferably, the first angle 301 is between 40° and 50°. A thickness of the first superconducting electrode 110 is not particularly limited and can for example be 50-300 nm e.g. 50 nm, 100 nm, 150 nm , 200 nm, 250 nm, 300 nm or any values therebetween.

In FIG. 3E, a second oblique PVD process directed towards the second side surface 103c of the fin structure 103 is executed to form the tunnel barrier 120, the tunnel barrier layer 125 and the tunnel barrier layer 127. No deposition is accomplished on the first side surface 103b of the fin structure 103 or the second portion 113 of the first superconducting electrode 110. Arrows herein represent vapor directions of PVD. A second angle 303 represents an angle between the vapor directions and the X direction. The second angle 303 is larger than 0° and smaller than 90°. Preferably, the second angle 303 is between 5° and 85° e.g. 5°, 10°, 20°, 30°, 40°, 45°, 50°, 60°, 70°, 80°, 85° or any values therebetween. Preferably, the second angle 303 is between 30° and 60°. Preferably, the second angle 303 is between 40° and 50°. A thickness of the tunnel barrier 120 is not particularly limited and can for example be 1-10 nm e.g. 1 nm, 2 nm, 3 nm , 4 nm, 5 nm, 6 nm, 7 nm, 8 nm, 9 nm, 10 nm or any values therebetween.

In FIG. 3F, a third oblique PVD process directed towards the second side surface 103c of the fin structure 103 is executed to form the second superconducting electrode 130 and the top electrode layer 137. No deposition is accomplished on the first side surface 103b of the fin structure 103 or the second portion 113 of the first superconducting electrode 110. As a result, the device 300 can become the device 100A. Arrows herein represent vapor directions of PVD. A third angle 305 represents an angle between the vapor directions and the X direction. The third angle 305 is larger than 0° and smaller than 90°. Preferably, the third angle 305 is between 5° and 85° e.g. 5°, 10°, 20°, 30°, 40°, 45°, 50°, 60°, 70°, 80°, 85° or any values therebetween. Preferably, the third angle 305 is between 30° and 60°. Preferably, the third angle 305 is between 40° and 50°. A thickness of the second superconducting electrode 130 is not particularly limited and can for example be 50-300 nm e.g. 50 nm, 100 nm, 150 nm , 200 nm, 250 nm, 300 nm or any values therebetween.

While not shown, a capping layer can be formed conformally over the device 300 in FIG. 3F to cover the second superconducting electrode 130, the top electrode layer 137 and an exposed portion of the first superconducting electrode 110.

Additionally, the device 300 in FIG. 3F can be patterned to etch or remove the first short-circuited junction structure 143, the second short-circuited junction structure 145 or both. The device 300 can therefore become the device 100B.

In FIG. 3G, a first contact structure 107 and a second contact structure 109 can be formed to respectively connect to the first superconducting electrode 110 and the second superconducting electrode 130. In this embodiment, the first contact structure 107 is in direct contact with the third portion 115 of the first superconducting electrode 110 while the second contact structure 109 is in direct contact with the third portion 135 of the second superconducting electrode 130. It should be noted that such positions of the first contact structure 107 and the second contact structure 109 are shown merely for illustrative purposes and are not limiting. For instance, the first contact structure 107 can be formed to be in direct contact with the second portion 113 of the first superconducting electrode 110, the third portion 115 of the first superconducting electrode 110 and/or the top electrode layer 137. In other words, the first contact structure 107 can be formed directly on top of the top electrode layer 137 as a conductive contact is formed between the top electrode layer 137 and the first superconducting electrode 110. The second contact structure 109 can be formed to be in direct contact with any part of the second superconducting electrode 130 such as the first portion 131, the second portion 133, the third portion 135 and/or the recess 134. Such placement of the first contact structure 107 and/or the second contact structure 109 can enable more flexibility in pattern design.

Referring back to FIGS. 3D, 3E and 3F, three oblique PVD processes are described for illustrative purposes. It should be noted that other vapor deposition techniques can be used alternatively or additionally. Examples of such vapor deposition techniques include, but are not limited to, PVD, atomic layer deposition (ALD), chemical vapor deposition (CVD) and the like. Additionally, the first angle 301, the second angle 303 and the third angle 305 are independent of each other and may or may not be the same. Preferably, the second angle 303 and the third angle 305 are the same. Preferably, the first angle 301, the second angle 303 and the third angle 305 are the same.

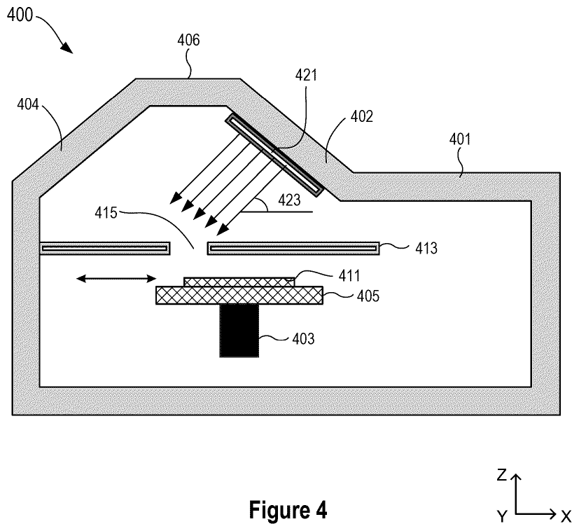

FIG. 4 shows a vertical cross-sectional view of a deposition chamber 400 in accordance with some embodiments of the present disclosure. The deposition chamber 400 can be used to execute the three oblique deposition processes in FIGS. 3E-3G. Detailed descriptions of the deposition chamber 400 and the corresponding semiconductor processing tool can be found in Applicant's issued Pat. Nos. 11,495,446 B2 and 11,220,741 B2,both of which are incorporated herein by reference in their entirety.

Briefly speaking, the deposition chamber 400 includes a housing 401 having a slanted roof 402 below which at least one target holder 421 is installed or attached. At least one target can be positioned in the target holder 421. The at least one target can include at least one material containing a constituent element of a film to be formed and may include a conductive material, a dielectric material, etc. During operation, vapors can be generated from the at least one target. Arrows herein represent vapor directions. A vapor angle 423 represents an angle between the vapor directions and the X direction and can represent the first angle 301, the second angle 303 and/or the third angle 305.

The deposition chamber 400 also includes a shielding plate 413 having an opening 415. The shielding plate 413 blocks vapor species from the target holder 421 whereas the opening 415 allows vapor species to pass through. The opening 415 may have various shapes depending on specific applications and be referred to as a gap, a passage hole, etc. A wafer stage 405 having a robotic shaft 403 attached thereto is positioned below the shielding plate 413. A wafer 411 can be placed on the wafer stage 405 and may represent the device 300. During operation, the robotic shaft 403 can move the wafer 411 laterally back and forth in the X direction or oscillate in the X direction. Such oscillation below the opening 415 can improve uniformity with oblique deposition.

Referring to FIGS. 3D, 3E, 3F and 4, the deposition chamber 400 can include three target holders 421 for the three oblique deposition processes. The wafer 411 may be rotated by about 180° around a central axis of the wafer 411 by the robotic shaft 403 between the first oblique process in FIG. 3D and the second oblique process in FIG. 3E. Alternatively, one or more target holders (not shown) can be installed below a slanted roof 404 of the housing 401 so that such wafer rotation may not be needed.

Moreover, the three oblique deposition processes in FIGS. 3D-3F can be executed in the deposition chamber 400 with no vacuum break, no oxide removal and no protective film. That is, the wafer 411 (or the device 300) does not need to leave the deposition chamber 400 during (or throughout) the three oblique deposition processes. Consequently, the tunnel barrier 120 can be formed in situ over the first superconducting electrode 110, without having to remove a surface oxide (such as a native oxide) of the first superconducting electrode 110 as is often required by conventional techniques. Similarly, the second superconducting electrode 130 can be formed in situ over the tunnel barrier 120. Additionally, the reaction barrier layer 105 can be formed in situ over the substrate 101 and the fin structure 103 in FIG. 3C for example by a target emitted from a horizontal roof 406 of the housing 401. That is to say, deposition processes described in FIGS. 3C-3F can all be executed in situ in the deposition chamber 400. Additionally, the aforementioned capping layer can be formed in situ over the second superconducting electrode 130, before the wafer 411 is removed from the deposition chamber 400 for further processing such as the process shown in FIG. 3G.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a substrate;
a fin structure formed on the substrate;
a first superconducting electrode;
a tunnel barrier; and
a second superconducting electrode, wherein
in a vertical direction that is substantially perpendicular to a working surface of the substrate, a first portion of the second superconducting electrode is formed on a first portion of the tunnel barrier that is formed on a first portion of the first superconducting electrode which is formed on a top surface of the fin structure, and
in a horizontal direction that is substantially parallel to the working surface of the substrate, a second portion of the first superconducting electrode is formed on a first side surface of the fin structure, and a second portion of the second superconducting electrode is formed on a second portion of the tunnel barrier that is formed on a second side surface of the fin structure.

2. The semiconductor device of claim 1, wherein:
the first side surface of the fin structure and the second side surface of the fin structure are on opposite sides of the fin structure.

3. The semiconductor device of claim 1, wherein:
the second portion of the tunnel barrier is in direct contact with an edge of the first portion of the first superconducting electrode.

4. The semiconductor device of claim 1, wherein:
the tunnel barrier is L-shaped.

5. The semiconductor device of claim 1, wherein:
the first superconducting electrode and the second superconducting electrode each independently comprise one selected from the group consisting of an elemental superconducting metal, a superconducting alloy and a superconducting nitride.

6. The semiconductor device of claim 5, wherein:
the elemental superconducting metal includes niobium (Nb), tantalum (Ta), aluminum (Al) or a combination thereof,
the superconducting alloy includes NbTi, WSi or a combination thereof, and
the superconducting nitride includes NbN, NbTiN or a combination thereof.

7. The semiconductor device of claim 1, wherein:
the tunnel barrier comprises one selected from the group consisting of a non-superconducting metal nitride and a non-superconducting metal oxide.

8. The semiconductor device of claim 7, wherein:
the non-superconducting metal nitride includes tantalum nitride, aluminum nitride or a combination thereof, and
the non-superconducting metal oxide includes tantalum oxide, aluminum oxide or a combination thereof.

9. The semiconductor device of claim 1, further comprising a short-circuited junction structure comprising:
a third portion of the first superconducting electrode;
a tunnel barrier layer formed over the third portion of the first superconducting electrode; and
a top electrode layer formed over the tunnel barrier layer and around an edge of the tunnel barrier layer to be in direct contact with the third portion of the first superconducting electrode.

10. The semiconductor device of claim 1, further comprising a short-circuited junction structure comprising:
a bottom electrode layer;
a tunnel barrier layer formed over the bottom electrode layer; and
a third portion of the second superconducting electrode formed over the tunnel barrier layer and around an edge of the tunnel barrier layer to be in direct contact with the bottom electrode layer.

11. The semiconductor device of claim 10, wherein:
the second superconducting electrode has a recess between the second portion of the second superconducting electrode and the third portion of the second superconducting electrode.

12. The semiconductor device of claim 1, further comprising:
a reaction barrier layer formed between the fin structure and the first superconducting electrode and between the fin structure and the tunnel barrier, wherein the reaction barrier layer is respectively in direct contact with the fin structure, the first superconducting electrode and the tunnel barrier.

13. A method of manufacturing a semiconductor device, comprising:
forming a first superconducting electrode over a fin structure on a substrate;
forming a tunnel barrier over the first superconducting electrode; and
forming a second superconducting electrode over the tunnel barrier, wherein
in a vertical direction that is substantially perpendicular to a working surface of the substrate, a first portion of the second superconducting electrode is formed on a first portion of the tunnel barrier that is formed on a first portion of the first superconducting electrode which is formed on a top surface of the fin structure, and
in a horizontal direction that is substantially parallel to the working surface of the substrate, a second portion of the first superconducting electrode is formed on a first side surface of the fin structure, and a second portion of the second superconducting electrode is formed on a second portion of the tunnel barrier that is formed on a second side surface of the fin structure.

14. The method of claim 13, further comprising:
executing a first oblique deposition process directed towards the first side surface of the fin structure to form the first superconducting electrode.

15. The method of claim 14, further comprising:
executing a second oblique deposition process directed towards the second side surface of the fin structure to form the tunnel barrier.

16. The method of claim 15, further comprising:
executing a third oblique deposition process directed towards the second side surface of the fin structure to form the second superconducting electrode.

17. The method of claim 16, wherein:
the first oblique deposition process, the second oblique deposition process and the third oblique deposition process are executed in a common deposition chamber.

18. The method of claim 17, wherein:
executing the second oblique deposition process comprises forming the tunnel barrier in situ on the first superconducting electrode without an oxide-removing process.

19. The method of claim 17, further comprising:
rotating the substrate by about 180 degrees between executing the first oblique deposition process and executing the second oblique deposition process.

20. The method of claim 17, further comprising:
forming a reaction barrier layer over the fin structure before executing the first oblique deposition process, the second oblique deposition process and the third oblique deposition process.
